(19) United States
(12) Patent Application Publication
(10) Pub. No.: US 2026/0150567 A1
(43) Pub. Date: May 28, 2026

(54) METHOD FOR MANUFACTURING ANTI-GLARE COVER, METHOD FOR MANUFACTURING OLED DISPLAY UNIT, ANTI-GLARE COVER, AND OLED DISPLAY UNIT

(71) Applicant: AGC Inc., Tokyo (JP)

(72) Inventors: Masanobu ISSHIKI, Tokyo (JP); Aichi INOUE, Tokyo (JP); Tatsuya IWASAKI, Tokyo (JP); Yuki AKAMA, Tokyo (JP)

(73) Assignee: AGC Inc., Tokyo (JP)

(21) Appl. No.: 19/454,279

(22) Filed: Jan. 20, 2026

Related U.S. Application Data
(63) Continuation of application No. PCT/JP2024/024718, filed on Jul. 9, 2024.

(30) Foreign Application Priority Data
Jul. 27, 2023 (JP) 2023-122410

(51) Int. Cl. H10K 59/80; H10K 59/12

(52) U.S. Cl. CPC H10K 59/8791; H10K 59/1201

(57) ABSTRACT

A method for manufacturing an anti-glare cover is a method for manufacturing an anti-glare cover provided on an image display surface of an Organic Light Emitting Diode (OLED) display. The anti-glare cover includes an anti-glare substrate having an irregular surface on a surface on a side opposite to the image display surface of the OLED display and a light-scattering layer disposed between the anti-glare substrate and the OLED display. The manufacturing method includes selecting a combination of the anti-glare substrate with the light-scattering layer which satisfies Equations (1), (2), and (3) in the specification, and forming the anti-glare substrate and the light-scattering layer in the selected combination.

### INCORPORATION BY REFERENCE

This application is based upon and claims the benefit of priority from Japanese patent application No. 2023-122410, filed on Jul. 27, 2023, and PCT application No. PCT/JP2024/024718 filed on Jul. 9, 2024, the disclosure of which is incorporated herein in its entirety by reference.

### BACKGROUND

The present disclosure relates to a method for manufacturing an anti-glare cover, a method for manufacturing an OLED display unit, an anti-glare cover, and an OLED display unit.

A display such as a liquid display includes an image display surface that displays an image. It has been studied to suppress regular reflection of external light on the image display surface and suppress reflection (i.e., projection) of external light by arranging an anti-glare film on an image display surface.

An anti-glare film disclosed in Japanese Unexamined Patent Application Publication No. 2007-101912 includes a first resin layer and a second resin layer. The first resin layer is formed of a translucent resin containing fine particles. The second resin layer is formed of a translucent resin having an irregular shape on a surface on the side opposite to the side on which the first resin layer is formed.

The second resin layer disclosed in Japanese Unexamined Patent Application Publication No. 2007-101912 has an irregular shape on its surface, thereby diffusing reflected light and suppressing reflection (i.e., projection) of external light. However, by forming the irregular shape on the surface of the second resin layer, a phenomenon called sparkle occurs.

The sparkle is caused by unevenness acting as fine lenses. The sparkle tends to occur when the focus of a lens is aligned with positions of pixels of a display. Further, it has been considered that the higher the pixel density, the more likely sparkle will occur.

The first resin layer disclosed in Japanese Unexamined Patent Application Publication No. 2007-101912 contains fine particles inside the translucent resin. These fine particles scatter transmitted light, which suppresses sparkle in an image.

### SUMMARY

An Organic Light Emitting Diode (OLED) display may be used in place of a liquid display. It is possible that, even when sparkle in an image in a liquid display can be successfully suppressed by using an anti-glare film having a conventional configuration, sparkle in an image in the OLED display may not be suppressed.

In order to suppress sparkle in an image, it is effective to scatter transmitted light in a light-scattering layer like in Japanese Unexamined Patent Application Publication No. 2007-101912. However, scattering of the transmitted light may cause white blurring in an image and a decrease in clarity of the image. Conditions under which sparkle in an image, white blurring in the image, and a decrease in the clarity of the image can be suppressed in anti-glare covers for OLED displays have been conventionally unknown.

The present inventors have found that a ratio of the light-emitting area of pixels significantly influences sparkle more than the aforementioned pixel density does, and that the smaller the ratio of the light-emitting area, the greater the sparkle in an image. The present inventors have also found that, since the ratio of the light-emitting area in OLED displays is often smaller than that in conventional liquid displays, sparkle in an image tends to be significantly greater in the OLED displays.

One aspect of the present disclosure is to provide a technique for suppressing sparkle in an image, white blurring in the image, and a decrease in clarity of the image in an anti-glare cover for an OLED display.

A method for manufacturing an anti-glare cover according to one aspect of the present disclosure is a method for manufacturing an anti-glare cover provided on an image display surface of an Organic Light Emitting Diode (OLED) display. The anti-glare cover includes an anti-glare substrate having an irregular surface on a surface on a side opposite to the image display surface of the OLED display and a light-scattering layer disposed between the anti-glare substrate and the OLED display. The OLED display includes a plurality of pixels, and each of the pixels includes red subpixels that emit red light, green subpixels that emit green light, and blue subpixels that emit blue light. A ratio (ΔA_{G}/A0) of a difference ΔA_{G} (ΔA_{G}=A0-A1_{G}) between an average value A0 of a total area of each of the pixels and an average value A1_{G} of a total light-emitting area of all the green subpixels included in each of the pixels to the average value A0 is 85% to 95%. A pixel density is 170 ppi to 650 ppi. The manufacturing method includes:
selecting a combination of the anti-glare substrate with the light-scattering layer that satisfies the following Equations (1), (2), and (3):

$$S 1 \times ( {a}_{S} \times {H}^{2} + {b}_{S} \times H + {c}_{S} ) + {d}_{S} = S 3 < 6.79 \qquad Equation ( 1 )$$

(in Equation (1), aₛ is 6.28×10⁻⁵, bₛ is −1.61×10⁻², cₛ is 9.13 ×10⁻¹, and dₛ is 1.8);

$$M 1 \times {d}_{M} + ( {a}_{M} \times {H}^{2} + {b}_{M} \times H + {c}_{M} ) = M 3 \leq 0.067 \qquad Equation ( 2 )$$

(in Equation (2), a_{M} is 9.45 ×10⁻⁷, b_{M} is 1.24×10⁻⁴, c_{M} is −5.49 ×10⁻⁵, and d_{M} is 1); and

$$C 1 \times ( {a}_{C} \times {H}^{2} + {b}_{C} \times H + {c}_{C} ) + {d}_{C} = C 3 \geq 35. \qquad Equation ( 3 )$$

(in Equation (3), a_{c} is −7.05×10⁻⁵, b_{c} is 6.30×10⁻⁵, c_{c} is 8.88 ×10⁻¹, and d_{c} is 3.6); and forming the anti-glare substrate and the light-scattering layer in the selected combination.

First sparkle index value S1: the anti-glare substrate is installed on the image display surface of the OLED display with its irregular surface facing up without the light-scattering layer interposed therebetween. The image display surface of the OLED display is imaged through the anti-glare substrate by a camera of a measurement device SMS-1000 manufactured by D&MS in a state in which only the green subpixels, of the pixels, emit light. A Sparkle value obtained by performing image analysis by the measurement device is the first sparkle index value S1. S1 is expressed by %. A distance between a light shielding plate attached to the camera and the anti-glare substrate is about 600 mm. As the lens of the camera, a 23FM50SP lens having a focal distance of 50 mm is used at an aperture of 16.

First white blurring index value M1: the anti-glare substrate is installed horizontally on the image display surface of the OLED display with its irregular surface facing up without the light-scattering layer interposed therebetween. Green light having a wavelength of 525 nm is made incident on the irregular surface at an incident angle of 40° by using Mini-Diff V2 manufactured by Synopsys, and a bidirectional reflectance distribution function (BRDF) is measured on the incident surface (a plane including a normal line at a point of incidence and incident light) in a direction of a reflection angle of 20°. A measurement value of BRDF is the first white blurring index value M1. The unit of M1 is (1/sr).

First clarity index value C1: the anti-glare substrate is installed on the image display surface of the OLED display with its irregular surface facing up without the light-scattering layer interposed therebetween. A stripe pattern with alternating white and black lines is imaged through the anti-glare substrate by a camera of a measurement device SMS-1000 manufactured by D&MS in a state in which the OLED display displays the stripe pattern. Each of the white lines is formed by turning on two consecutive pixels in a width direction of the white line. Each of the black lines is formed by turning off two consecutive pixels in a width direction of the black line. A value obtained by measuring an intensity distribution of the captured image and substituting a peak value Sp1 and a valley value Sv1 of the intensity distribution into the following Equation (4) is the first clarity index value C1. C1 is expressed by %.

$$C 1 = ( Sp 1 - Sv 1 ) / ( Sp 1 + Sv 1 ) \times 100 \qquad Equation ( 4 )$$

As the lens of the camera, a 23FM50SP lens having a focal distance of 50 mm is used at an aperture of 16. A distance between the light shielding plate attached to the camera and the anti-glare substrate is set in such a way that an absolute value of an optical magnification m becomes 0.0962. A focus of the lens is aligned with pixels of the OLED display.

Haze value H: a percentage of transmitted light that is deviated from the incident light by 2.5° or more by forward scattering, of transmitted light that transmits through the light-scattering layer in a thickness direction, is the Haze value H.

According to one aspect of the present disclosure, it is possible to suppress sparkle in an image, white blurring in the image, and a decrease in clarity of the image in an anti-glare cover for an OLED display.

The above and other objects, features and advantages of the present disclosure will become more fully understood from the detailed description given hereinbelow and the accompanying drawings.

### BRIEF DESCRIPTION OF DRAWINGS

FIG. 1 is a cross-sectional view showing an OLED display unit according to one embodiment;

FIG. 2 is a flowchart showing one example of a method for manufacturing an anti-glare substrate;

FIG. 3 is a cross-sectional view showing one example of a curvingly-recessed surface formed from a microcrack;

FIG. 4 is a plan view showing a configuration example of pixels of the OLED display;

FIG. 5 is a diagram showing one example of a relation between ΔA_{G}/A0 and S1 and a relation between ΔAB/A0 and S4;

FIG. 6 is a diagram showing one example of combinations of anti-glare substrates with light-scattering layers, and characteristic values thereof;

FIG. 7 is a diagram showing a relation between S1 and S2 shown in FIG. 6 for each H;

FIG. 8 is a diagram showing a relation between a slope of a linear equation shown in FIGS. 7 and H;

FIG. 9 is a diagram showing a relation between M1 and M2 shown in FIG. 6 for each H;

FIG. 10 is a diagram showing a relation between an intercept of a linear equation shown in FIGS. 9 and H;

FIG. 11 is a diagram showing a relation between C1 and C2 shown in FIG. 6 for each H;

FIG. 12 is a diagram showing a relation between a slope of a linear equation shown in FIGS. 11 and H; and

FIG. 13 is a diagram showing a predicted value for each of combinations of the anti-glare substrates and the light-scattering layers shown in FIG. 6.

### DESCRIPTION OF EMBODIMENTS

Hereinafter, with reference to the drawings, embodiments for implementing the present disclosure will be described. The same or corresponding components in the respective drawings are denoted by the same reference numerals, and the description thereof may be omitted. In the specification, “to” indicating a numerical range means that the numerical values described as a starting value and an ending value of the numerical range are included in the range as a lower limit value and an upper limit value. The numerical range includes rounded values.

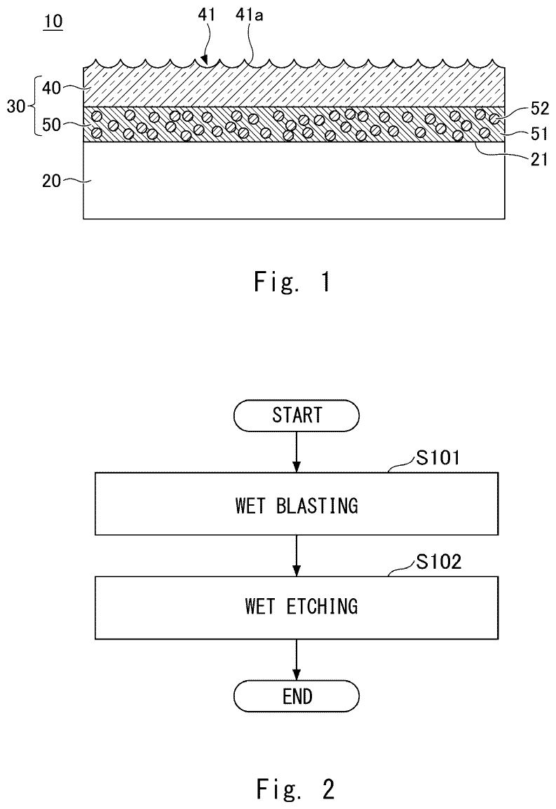

With reference to FIG. 1, an OLED display unit 10 according to one embodiment will be described. The OLED display unit 10 includes an OLED display 20 and an anti-glare cover 30. The OLED display 20 includes an image display surface 21 that displays an image. The anti-glare cover 30, which is provided on the image display surface 21 of the OLED display 20, suppresses regular reflection of external light and reflection (i.e., projection) of external light.

The anti-glare cover 30 includes an anti-glare substrate 40 and a light-scattering layer 50 that is disposed between the anti-glare substrate 40 and the OLED display 20. The anti-glare substrate 40 includes an irregular surface 41a on a surface 41 which is on the side opposite to the image display surface 21 of the OLED display 20. The irregular surface 41a is formed on at least a portion of the surface 41. The irregular surface 41a diffuses reflected light and suppresses reflection (i.e., projection) of external light.

The anti-glare substrate 40 is, for example, a glass substrate, and the irregular surface 41a is formed of glass. The glass is, for example, aluminosilicate glass, alkali aluminosilicate glass, soda lime glass, borosilicate glass, phosphorus silicate glass, alkali aluminoborosilicate glass, lead glass, alkali barium glass, or aluminoborosilicate glass. More specifically, the following glasses (i) to (v) are mentioned.
(i) A glass that contains 50% to 80% SiO₂, 0% to 26% Al₂O₃, 1% to 25% Na₂O, 0% to 10% B₂O₃, 0 to 20% K₂O, 0% to 20% MgO, and 0% to 15% CaO in mole percentage on an oxide basis.
(ii) A glass that contains 50% to 80% SiO₂. 2% to 25% Al₂O₃, 0% to 10% Li₂O, 0% to 18% Na₂O, 0% to 10% K₂O, 0% to 15% MgO, 0% to 5% CaO, and 0% to 5% ZrO₂ in mole percentage on an oxide basis.
(iii) A glass that contains 50% to 74% SiO₂, 1% to 10% Al₂O₃, 6% to 14% Na₂O, 3% to 11% K₂O, 2% to 15% MgO, 0% to 6% CaO, and 0% to 5% ZrO₂ in mole percentage on an oxide basis, with a total SiO₂ and Al₂O₃content of 75% or less, a total Na₂O and K₂O content of 12% to 25%, and a total MgO and CaO content of 7% to 15%.
(iv) A glass that contains 68% to 80% SiO₂, 4% to 10% Al₂O₃, 5% to 15% Na₂O, 0% to 1% K₂O, 4% to 15% MgO, and 0% to 1% ZrO₂ in mole percentage on an oxide basis.
(v) A glass that contains 67% to 75% SiO₂, 0% to 4% Al₂O₃, 7% to 15% Na₂O, 1% to 9% K₂O, 6% to 14% MgO, and 0% to 1.5% ZrO₂ in mole percentage on an oxide basis, with a total SiO₂ and Al₂O₃ content of 71% to 75%, a total Na₂O and K₂O content of 12% to 20%, and a CaO content of less than 1%.

While the anti-glare substrate 40 is a glass substrate in this embodiment, the anti-glare substrate 40 may be any substrate through which visible light can transmit, and may be, for example, a resin substrate. Note that glass has higher weatherability and scratch resistance than resin. Further, while the anti-glare substrate 40 is a flat plate in this embodiment, it may be a curved plate. The thickness of the anti-glare substrate 40 is preferably 5 mm or less, and more preferably 3 mm or less. Further, the thickness of the anti-glare substrate 40 is preferably 0.2 mm or more, and more preferably 0.3 mm or more.

With reference to FIG. 2, one example of a method for manufacturing the anti-glare substrate 40 will be described. The method for manufacturing the anti-glare substrate 40 includes, for example, obtaining the irregular surface 41a by performing wet blasting (Step S101) and wet etching (Step S102) on at least a portion of the surface 41 of the anti-glare substrate 40 in this order. The method for forming the irregular surface 41a is not particularly limited, and may be a general one. For example, sand blasting may be performed in place of wet blasting.

It should be noted that the method for manufacturing the anti-glare substrate 40 may include processes other than Steps S101 and S102. For example, after Steps S102, the anti-glare substrate 40 may be chemically strengthened. A chemically strengthening process is a process of forming a compressive stress layer on a glass surface by ion exchange at a temperature equal to or lower than a glass transition point. The compressive stress layer is formed by exchanging alkali metal ions having a small ionic radius contained in the glass with alkali ions having a larger ionic radius.

Step S101 includes performing wet blasting at least on a portion of the surface 41 of the anti-glare substrate 40. The wet blasting is a process of forming minute cracks (microcracks) in an object by jetting a slurry containing particles from a nozzle under pressure of a gas and impinging on the object.

The slurry includes particles described in the following and a dispersion medium. Examples of the dispersion medium include water, a water-soluble organic solvent, or a mixture of water and a water-soluble organic solvent. Examples of the water-soluble organic solvent include lower alcohols and ketones. Examples of the lower alcohols include methanol, ethanol, n-propanol, isopropanol, n-butanol, sec-butanol, or tert-butanol. One example of the ketones is acetone.

The slurry may also contain a dispersion aid. Examples of the dispersion aid include carboxymethyl cellulose, a polyacrylic acid derivative or a salt thereof, a polycarboxylic acid derivative or a salt thereof, or polyureurethane. Examples of the polyacrylic acid derivative or the salt thereof include polyacrylic acid, a polyacrylic acid ammonium salt, a polyacrylic acid sodium salt, a polyacrylamide, an acrylic ester-acrylate copolymer, an acrylamide-acrylate copolymer, or a copolymer of an acrylic ester acrylamide-acrylate salt. Examples of the polycarboxylic acid derivative or a salt thereof include a polycarboxylic acid ammonium salt or a polycarboxylic acid sodium salt. A ratio of the dispersion aid in the slurry is preferably 0.03 mass % or more and 2.0 mass % or less.

The particles contained in the slurry are preferably particles having higher Mohs hardness than glass from a viewpoint of processability, and are preferably inorganic particles other than spherical particles. The inorganic particles may be made of a metal (containing alloys) or an inorganic compound. The inorganic compound may be a metal compound or a non-metal compound. Examples of the metal include stainless steel, zinc, copper, and the like. Examples of the inorganic compound include silica, glass, garnet, zirconia, alumina, silicon carbide, boron carbide, CO₂ (dry ice), and the like. Among these, alumina is preferable. As the particles contained in the slurry, a commercial product can be used. Examples of the commercial product include white alumina manufactured by Fujimi Incorporated.

The concentration of the particles in the slurry is preferably 0.05 mass % or higher from the viewpoint of productivity, and more preferably 0.1 mass % or higher. On the other hand, the concentration of the particles in the slurry is preferably 30 mass % or lower, and more preferably 10 mass % or lower from a viewpoint of fluidity of the slurry.

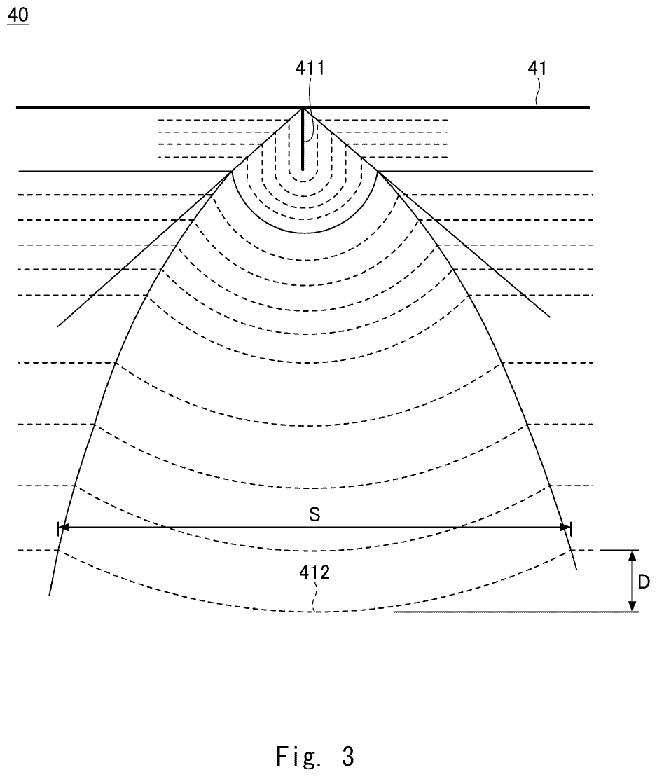

In the wet blasting, as shown in FIG. 3, microcracks 411 are formed in at least a portion of the surface 41. Then, in Steps S102 described in the following, the glass is etched isotropically starting from the microcrack 411 as illustrated in FIG. 3, so that the curvingly-recessed surface 412 can be formed. In FIG. 3, a plurality of broken lines indicate changes in the surface shape of the glass with time. When the glass is etched isotropically, the depth D of the curvingly-recessed surface 412 is equivalent to a depth of the microcrack 411.

The depth of the microcrack 411 varies depending on the particle diameter of the particles, etc. The greater the particle diameter of the particles, the greater the impact of the particles and the greater the depth of the microcrack 411. The greater the depth of the microcrack 411, the greater the area S of the curvingly-recessed surface 412 in plan view. The greater the depth of the microcrack 411, the greater the depth D of the curvingly-recessed surface 412.

Step S102 includes performing wet etching on at least a portion of the surface 41 of the anti-glare substrate 40. The wet etching is a process in which an etchant containing an acid or an alkali is supplied to the surface 41 of the anti-glare substrate 40 to form a curvingly-recessed surface 412 starting from the microcrack 411. A method of supplying the etchant may be a dip method in which the glass plate is immersed in the etchant, or a spray method in which the etchant is applied to the glass plate. The wet etching enables isotropic etching of glass as compared with dry etching.

The etchant is, for example, a solution containing an acid. An acid concentration in the etchant is preferably 1 to 15 mass %, and particularly preferably 3 to 10 mass %. As the acid, for example, hydrogen fluoride is used. A combination of hydrogen fluoride and hydrogen chloride may be used.

When the etchant is a solution containing acid, etching is preferably performed at a temperature of 10° C. to 40° C., preferably 15° C. to 35° C., for 2 minutes to one hour.

When the etchant is a solution containing acid, an etching rate is preferably 0.5 μm/minute or more, more preferably 1.0 μm/minute or more, and still more preferably 2.0 μm/minute or more, from the viewpoint of sufficiently securing an anti-glare effect. The etching rate is preferably 20 μm/minute or less.

The etchant may be a solution containing alkali. An alkali concentration in the etchant is preferably 1 mass % to 50 mass %, and preferably 3 mass % to 50 mass %. As the alkali, at least one base selected from, for example, sodium hydroxide, potassium hydroxide, potassium carbonate, or sodium carbonate is used. These bases may be used alone or in combination.

The etchant preferably contains a chelating agent in addition to the alkali. The chelating agent suppresses recrystallization of the glass by forming a chelating complex with a metal ion of the glass dissolved in the etchant. A content of the chelating agent in the etchant is preferably from 0.1 mol/L to 0.5 mol/L. As the chelating agent, for example, ethylenediaminetetraacetic acid (EDTA), citric acid, gluconic acid, succinic acid, acid, oxalic tartaric acid, or hydroxyethylidenediphosphinic acid (HEDP) is used.

When the etchant is a solution containing an alkali, etching is preferably performed at a temperature of from 65° C. to 150° C., preferably from 80° C. to 150° C., for 20 minutes to 40 hours.

When the etchant is a solution containing an alkali, the etching rate is preferably at least 0.05 μm/minute, more preferably at least 0.10 μm/minute, and still more preferably at least 0.15 μm/minute from the viewpoint of sufficiently securing the anti-glare effect. The etching rate is preferably 1.50 μm/min or less.

Incidentally, by forming an irregular shape on the surface 41 of the anti-glare substrate 40, a phenomenon called sparkle occurs. The sparkle is caused by unevenness acting as fine lenses. The sparkle in an image is likely to occur when the focus of a lens is aligned with positions of pixels of the OLED display 20. Further, it has been considered that the higher the pixel density, the more likely sparkle will occur.

According to this embodiment, as will be described later, even when the pixel density is 170 ppi or more, it is possible to suppress sparkle in the image. The pixel density is, for example, 170 ppi or more, preferably 200 ppi or more, further preferably 250 ppi or more, and particularly preferably 270 ppi or more. The pixel density is, for example, 650 ppi or less, preferably 400 ppi or less, more preferably 350 ppi or less, and further preferably 300 ppi or less due to the limitations of the resolution of human eyes.

The light-scattering layer 50, which is disposed between the anti-glare substrate 40 and the OLED display 20, scatters the light that transmits from the OLED display 20 to the anti-glare substrate 40, thereby suppressing sparkle in the image. The light-scattering layer 50 includes, for example, a resin layer 51 and a plurality of particles 52 that disperse inside the resin layer 51. The resin layer 51 and the particles 52 have different refractive indices with respect to visible light. The light-scattering layer 50 scatters the transmitted light by the particles 52.

The light-scattering layer 50 may also serve as a bonding layer that bonds the anti-glare substrate 40 with the OLED display 20. The light-scattering layer 50 may be, for example, Optical Clear Adhesive (OCA) or the like. One example of commercially available OCAs is adhesive for opticₛ “DA-series” manufactured by TOMOEGAWA CORPORATION. If the resin layer 51 has adhesiveness, the light-scattering layer 50 can also serve as a bonding layer.

The resin layer 51 is not particularly limited, and may be made of any material that transmits visible light. The resin layer 51 is made of, for example, pressure-sensitive adhesive. Note that the resin layer 51 may be made of a UV curable resin, a thermosetting resin, a thermoplastic resin, or a water curable resin. The thickness of the resin layer 51 is preferably 5 μm to 500 μm. When the thickness of the resin layer 51 is 5 μm or more, particles 52 can easily scatter the transmitted light, sparkle in an image is likely to be suppressed, the particles 52 can be uniformly dispersed, and the OLED display 20 and the anti-glare substrate 40 can be uniformly bonded to each other. When the thickness of the resin layer 51 is 500 μm or less, the Haze value H of the light-scattering layer 50 becomes small, a reduction in image sharpness caused by an increase in the thickness of the light-scattering layer 50 can be minimized, and thus the image becomes clear.

The particles 52 may be made of either an inorganic material or an organic material. Examples of the material of the particles 52 may be polymethyl methacrylate, silica, polystyrene, and metal oxide. The average particle diameter of the particles 52 is preferably 0.1 μm to 100 μm. When the average particle diameter of the particles 52 is 0.1 μm or more, the particles 52 easily scatter the transmitted light, and sparkle in an image is likely to be suppressed. When the average particle diameter of the particles 52 is 100 μm or less, the Haze value H of the light-scattering layer 50 is small and the image becomes clear.

The particle size distribution of the particles 52 is measured using, for example, an electric resistance type particle size distribution measurement device Multisizer 4e manufactured by Beckman Coulter, Inc. The particle size distribution obtained using the particle size distribution measurement device described above is based on a so-called “Coulter principle”, in which an impedance change due to passage of each particle in an electrolyte solution through a measurement site is directly detected, the particle size of each particle is measured as a spherical equivalent particle size, and particle distribution is arranged in an integrated histogram (or an integrated frequency curve) with the particle size as a horizontal axis and the number (frequency) as a vertical axis. The average particle diameter is calculated as a so-called arithmetic average diameter, according to the number distribution.

The Haze value H of the light-scattering layer 50 is preferably 10% to 70%, more preferably 20% to 70%, further preferably 30% to 70%, and particularly preferably 50% to 70%. The Haze value H is obtained as a percentage of transmitted light that is deviated from the incident light by 2.5° or more by forward scattering, of the transmitted light that transmits through the light-scattering layer 50 in the thickness direction. The smaller the Haze value H, the clearer the image. The Haze value is measured using a C light source in accordance with the Japanese Industrial Standards (JIS K 7136:2000). Examples of a commercially available device that measures the Haze value H include, for example, a haze meter (HM-65L2) manufactured by Murakami Color Research Laboratory.

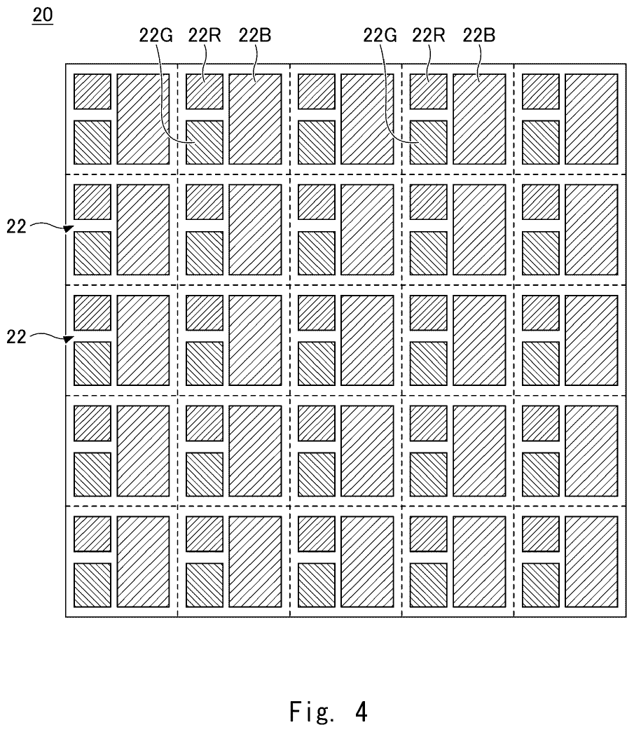

As shown in FIG. 4, the OLED display 20 includes a plurality of pixels 22, and each of the pixels 22 includes a red subpixel 22R that emits red light, a green subpixel 22G that emits green light, and a blue subpixel 22B that emits blue light. Each of the pixels 22 includes one or more red subpixels 22R, one or more green subpixels 22G, and one or more blue subpixels 22B. Note that the arrangement and the shape of the red subpixels 22R, the green subpixels 22G, and the blue subpixels 22B are not limited to the arrangement and the shape shown in FIG. 4, and may be general ones. Each of the pixels 22 may further include subpixels that emit light of other color (e.g., yellow).

In the OLED display 20, unlike liquid displays, the light-emitting area of the blue subpixels 22B is often greater than the light-emitting area of the red subpixels 22R and the light-emitting area of the green subpixels 22G. This is because the blue light-emitting material has a shorter lifespan and experiences a faster decrease in luminance than the red light-emitting material and the green light-emitting material. By increasing the light-emitting area of the blue subpixels 22B, a decrease in the luminance of the blue subpixels 22B can be delayed.

In the liquid displays, blue subpixels, red subpixels, and green subpixels normally have the same light-emitting area. In order to maximize the transmittance of the backlight, their light-emitting areas are generally made equal to each other and large.

The present inventors have studied a reason why sparkle in an image in the OLED display 20 may not be suppressed even when sparkle in an image in a liquid display can be successfully suppressed by using conventional anti-glare covers, and have focused on the point that the ratio of the light-emitting area of the blue subpixels 22B is large. It is considered that, since the ratio of the light-emitting area of the blue subpixels 22B is large, the ratio of the light-emitting area of the green subpixels 22G becomes small, which may cause sparkle in the image to occur when the green subpixels 22G are turned on.

The ratio of the light-emitting area of the green subpixels 22G is represented by (1−ΔA_{G}/A0) or (ΔA_{G}/A0). The greater the ΔA_{G}/A0, the smaller the ratio of the light-emitting area of the green subpixels 22G. A0 is an average value of a total area of each of the pixels 22. The total area of one pixel 22 is a sum of the light-emitting area of one pixel 22 and the non-light-emitting area of one pixel 22. The light-emitting area of one pixel 22 is a total area of all the subpixels forming one pixel 22 (e.g., the red subpixels 22R, the green subpixels 22G, and the blue subpixels 22B). ΔA_{G} is a difference (A0-A1_{G}) between A0 and A1G. A1G is an average value of the total light-emitting area of all the green subpixels 22G forming each of the pixels 22. When one pixel 22 includes two green subpixels 22G, A1G is a total light-emitting area of the two green subpixels 22G.

Likewise, the ratio of the light-emitting area of the blue subpixels 22B is represented by (1-ΔAB/A0) or (ΔAB/A0). The greater the ΔAB/A0, the smaller the ratio of the light-emitting area of the blue subpixels 22B. ΔAB is a difference (A0-A1B) between A0 and A1B. A1B is an average value of the total light-emitting area of all the blue subpixels 22B that form each of the pixels 22. When one pixel 22 includes two blue subpixels 22B, A1B is a total light-emitting area of the two blue subpixels 22B.

Further, the ratio of the light-emitting area of the red subpixels 22R is represented by (1-ΔAR/A0) or (ΔAR/A0). The greater the ΔAR/A0, the smaller the ratio of the light-emitting area of the red subpixels 22R. ΔAR is a difference (A0-A1_{R}) between A0 and A1R. A1R is an average value of the total light-emitting area of all the red subpixels 22R forming each of the pixels 22. When one pixel 22 includes two red subpixels 22R, A1R is a total light-emitting area of the two red subpixels 22R.

In a liquid display, each of ΔAR/A0, ΔA_{G}/A0 and ΔAB/A0 is normally about 70 to 85%. Further, in the liquid display, ΔAR/A0, ΔA_{G}/A0 and ΔAB/A0 are equal to one another. On the other hand, in an OLED display, ΔAR/A0, ΔA_{G}/A0 and ΔAB/A0 are each 70% to 95%. Further, in the OLED display, ΔAR/A0 and ΔA_{G}/A0 are substantially equal to each other, and are often greater than ΔAB/A0.

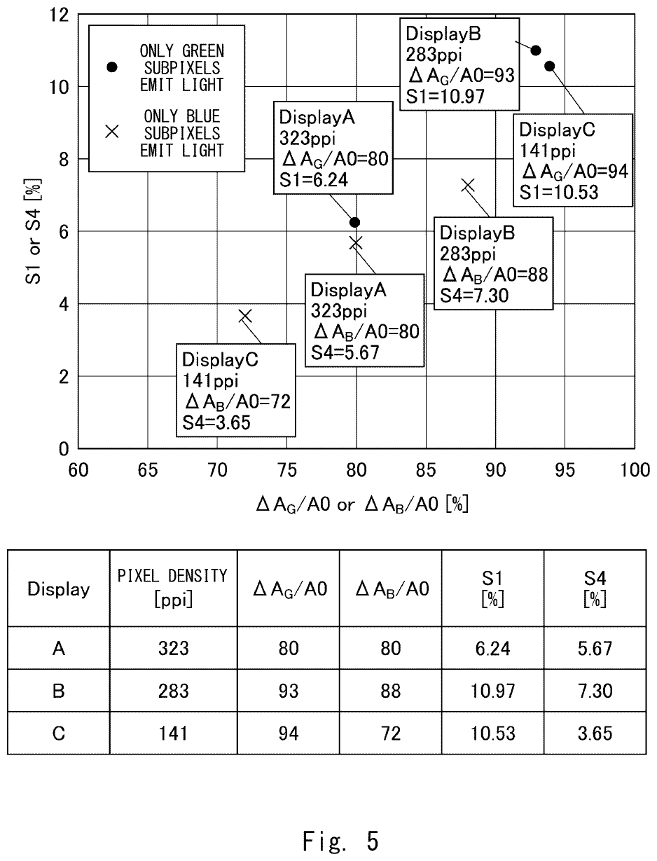

As shown in FIG. 5, the present inventors have studied a relation between ΔA_{G}/A0(%) and S1(%) and a relation between ΔAB/A0(%) and S4(%). Specifically, three types of commercially available OLED displays having different pixel densities were prepared, anti-glare covers having the same configuration were attached to the respective OLED displays, and the first sparkle index value S1 and the fourth sparkle index value S4 were each measured. While details of the first sparkle index value S1 and the fourth sparkle index value S4 will be described later, the first sparkle index value S1 and the fourth sparkle index value S4 each indicate a degree of sparkle in an image in the OLED display unit 10 that does not include the light-scattering layer 50 and includes the anti-glare substrate 40. The first sparkle index value S1 is measured in a state in which only the green subpixels 22G among the pixels 22 emit light. The fourth sparkle index value S4 is measured in a state in which only the blue subpixels 22B among the pixels 22 emit light. The smaller the first sparkle index value S1 and the fourth sparkle index value S4, the smaller the sparkle in the image, which enables the observer to easily observe the image.

The first sparkle index value S1 indicates a degree of sparkle in an image in the OLED display unit 10 in a case where the anti-glare cover 30 does not include the light-scattering layer 50 and includes only the anti-glare substrate 40. The smaller the first sparkle index value S1, the smaller the sparkle when a green image is displayed, which enables the observer to easily observe the image. The method for measuring the first sparkle index value S1 is as follows. The anti-glare substrate 40 is installed on the image display surface 21 of the OLED display 20 with the irregular surface 41a facing up without the light-scattering layer 50 interposed therebetween. The image display surface 21 of the OLED display 20 is imaged through the anti-glare substrate 40 by a camera of a measurement device SMS-1000 manufactured by D&MS in a state in which only the green subpixels 22G among the pixels 22 emit light. After the position of the anti-glare substrate 40 is shifted by 1.0 mm, the image display surface 21 of the OLED display 20 is imaged again through the anti-glare substrate 40. Then a Sparkle value, which is obtained by performing image analysis by inputting 0 to the Pixel Ratio value using a Difference Image Method (DIM) of the measurement device, is the first sparkle index value S1. S1 is expressed by %. The distance between a light shielding plate attached to the camera and the anti-glare substrate is set in such a way that the absolute value of an optical magnification m becomes 0.0962, and the focus of the lens of the camera is aligned with the pixels 22 of the OLED display 20. In this case, the distance between the light shielding plate attached to the camera and the anti-glare substrate 40 is about 600 mm. As the lens of the camera, a 23FM50SP lens having a focal distance of 50 mm is used at an aperture of 16. Further, in order to accurately adjust the aperture to 16, the light intensity value (Intensity) and the exposure time at an aperture of 2.8, which is fully open, are recorded, the exposure time is set to 32 times of the exposure time at the aperture of 2.8 in such a way that the area of the aperture becomes 1/32 of the case where the aperture is 2.8, and the aperture of the lens is adjusted in such a way that the light intensity value becomes the same as that of the case where the aperture is 2.8.

The fourth sparkle index value S4 indicates a degree of sparkle in an image in the OLED display unit 10 in a case where the anti-glare cover 30 does not include the light-scattering layer 50 and includes only the anti-glare substrate 40. The smaller the fourth sparkle index value S4, the smaller the sparkle when a blue image is displayed, which enables the observer to easily observe the image. The method for measuring the fourth sparkle index value S4 is similar to the method for measuring the first sparkle index value S1 except that the image display surface 21 of the OLED display 20 is imaged through the anti-glare substrate 40 by a camera of a measurement device SMS-4000 manufactured by D&MS in a state in which only the blue subpixels 22B among the pixels 22 emit light. S4 is expressed by %.

As shown in FIG. 5, in the “Display A”, ΔA_{G}/A0 is the same as ΔAB/A0, and S1 and S4 are about the same. This shows that, when the density of the pixels 22 is the same and the ratio of the light-emitting area is the same, the degree of sparkle in an image rarely depends on the emission color. Further, in both the “Display B” and the “Display C”, ΔA_{G}/A0 is greater than ΔAB/A0 and S1 is greater than S4. This shows that, even when the density of the pixels 22 is the same, the smaller the ratio of the light-emitting area, the more likely sparkle will occur in an image. FIG. 5 further shows that the ratio of the light-emitting area significantly influences sparkle more than the density of the pixels 22 does.

In the OLED display 20, ΔA_{G}/A0 is often designed to be greater than ΔAB/A0. This is because the blue light-emitting material has a shorter lifespan and experiences a faster decrease in luminance than the red light-emitting material and the green light-emitting material. It is considered that since the ratio of the light-emitting area of the blue subpixels 22B is large, the ratio of the light-emitting area of the green subpixels 22G becomes small, which may cause sparkle in the image to occur when the green subpixels 22G are turned on. Therefore, it is considered that sparkle in an image is more likely to occur in the OLED display than in the liquid display when the green subpixels 22G are turned on.

In order to suppress sparkle in an image, it is effective to scatter transmitted light in the light-scattering layer 50. However, scattering of the transmitted light may cause white blurring in an image and a decrease in clarity of an image. Conditions under which sparkle in an image, white blurring in the image, and a decrease in the clarity of the image can be suppressed in the anti-glare cover 30 for the OLED display 20 have been conventionally unknown.

The present inventors have studied a combination of the anti-glare substrate 40 with the light-scattering layer 50 in order to suppress sparkle in an image, white blurring in the image, and and the decrease in the clarity of the image in the anti-glare cover 30 for the OLED display 20. As a result, the present inventors have successfully found an appropriate combination, as will be described later, by using the aforementioned first sparkle index value S1(%), the first white blurring index value M1 (/sr) that will be described later, and the first clarity index value C1(%) that will be described later as characteristic values of the anti-glare substrate 40, and using the Haze value H (%) as the characteristic value of the light-scattering layer 50.

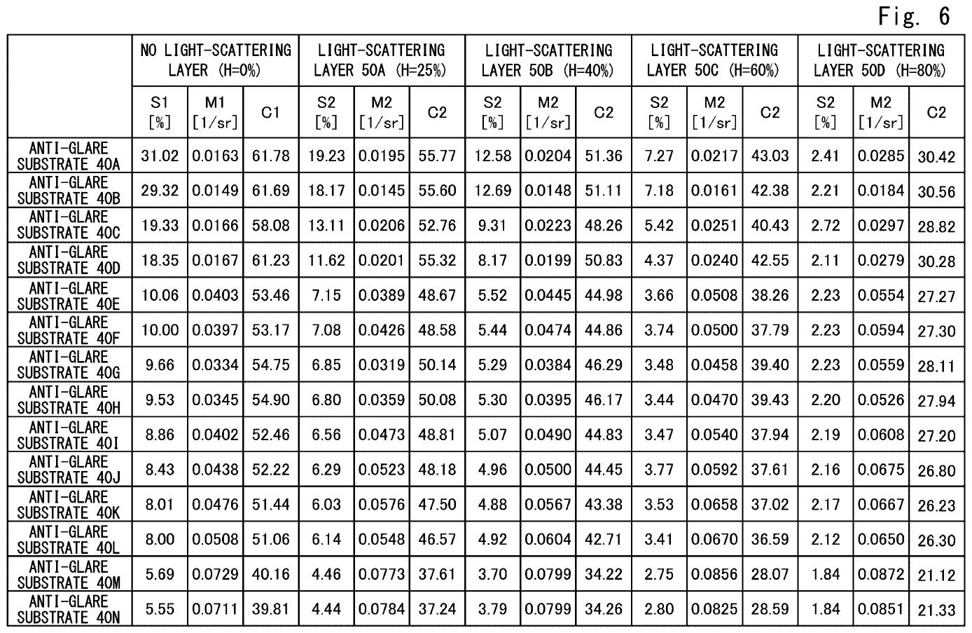

FIG. 6 shows one example of a combination of the anti-glare substrate 40 with the light-scattering layer 50 and characteristic values thereof. As the anti-glare substrate 40, the following anti-glare substrates 40A to 40N were prepared.
40A: Commercially available product manufactured by AGC Glass Europe (product name: VRD 130)
40B: Commercially available product manufactured by AGC Glass Europe (product name: VRD 140)
40C: Commercially available product manufactured by AGC Glass Europe (product name: LST 70)
40D: Commercially available product manufactured by AGC Glass Europe (product name: LST 120)
40E to 40F: Substrates obtained by performing wet blasting and wet etching on aluminosilicate glass in this order. In the wet blasting, a slurry containing alumina particles (particle size: #2000), a dispersion aid, and a dispersion medium (water) was used. In the wet etching, an aqueous solution containing hydrogen fluoride (HF) was used as the etchant. 40E to 40F were prepared under the same conditions except that the time during which glass is immersed in the etchant was changed. 40G to 40N: Substrates obtained by performing wet blasting and wet etching on aluminosilicate glass in this order. In the wet blasting, a slurry containing alumina particles (particle size: #4000), a dispersion aid, and a dispersion medium (water) was used. In the wet etching, an aqueous solution containing hydrogen fluoride (HF) and hydrogen chloride (HCl) was used as the etchant. 40G to 40N were prepared under the same conditions except that the time during which glass is immersed in the etchant was changed.

Further, the following light-scattering layers 50A to 50D were prepared as the light-scattering layer 50. Adhesives for opticₛ “DA-series”, standard type, manufactured by TOMOEGAWA CORPORATION, having different Haze values were used. The thicknesses of these adhesives were all 25 μm.
50A: Haze value 25%
50B: Haze value 40%
50C: Haze value 60%
50D: Haze value 80%

Further, as the OLED display 20, model number: TOP156UHD06OLED-0 manufactured by Shenzhen Top Electronic Parts Co., Limited was prepared. The pixel pitch was 89.64 μm and the pixel density was 283 ppi.

The first sparkle index value S1 is measured as described above.

The first white blurring index value M1 indicates a degree of white blurring in the image in the OLED display unit 10 in a case where the anti-glare cover 30 does not include the light-scattering layer 50 and includes only the anti-glare substrate 40. The smaller the first white blurring index value M1, the less white blurring appears in the image, which enables the observer to easily observe the image. The method for measuring the first white blurring index value M1 is as follows. In the measurement of the first white blurring index value M1, the OLED display 20 and the light-scattering layer 50 are not used. First, the anti-glare substrate 40 is installed on the image display surface 21 of the OLED display 20 with its irregular surface 41a facing up without the light-scattering layer 50 interposed therebetween. At this time, the gap between the OLED display 20 and the anti-glare substrate 40 is filled with water. Green light having a wavelength of 525 nm is made incident on the irregular surface 41a at an incident angle of 40° using Mini-Diff V2 manufactured by Synopsys, and a bidirectional reflectance distribution function (BRDF) is measured on the incident surface (a plane including a normal line at a point of incidence and incident light) in a direction of a reflection angle of 20°. The measurement value of BRDF is the first white blurring index value M1. In this example, measurement is performed in a reflection measurement mode. The unit of M1 is (1/sr).

The first clarity index value C1 indicates a degree of clarity of the image in the OLED display unit 10 in a case where the anti-glare cover 30 does not include the light-scattering layer 50 and includes only the anti-glare substrate 40. The greater the first clarity index value C1, the clearer the image, which enables the observer to easily observe the image. The method for measuring the first clarity index value C1 is as follows. The anti-glare substrate 40 is installed on the image display surface 21 of the OLED display 20 with its irregular surface 41a facing up without the light-scattering layer 50 interposed therebetween. A stripe pattern with alternating white and black lines is imaged through the anti-glare substrate 40 by a camera of a measurement device SMS-1000 manufactured by D&MS in a state in which the OLED display 20 displays the stripe pattern. Each of the white lines is formed by turning on two consecutive pixels 22 in a width direction of the white line. Each of the black lines is formed by turning off two consecutive pixels 22 in a width direction of the black line. A value obtained by measuring intensity distribution of the captured image and substituting a peak value Sp1 and a valley value Sv1 of the intensity distribution into the following Equation (4) is the first clarity index value C1. C1 is expressed by %.

$$C 1 = ( Sp 1 - Sv 1 ) / ( Sp 1 + Sv 1 ) \times 100 \qquad Equation ( 4 )$$

In this example, measurement is performed in a Distinctness of Image (DOI) measurement mode. As the lens of the camera, a 23FM50SP lens having a focal distance of 50 mm is used at an aperture of 16. The distance between the light shielding plate attached to the camera and the anti-glare substrate 40 is set in such a way that the absolute value of the optical magnification m becomes 0.0962, and the focus of the lens is aligned with the pixels 22 of the OLED display 20.

The second sparkle index value S2 indicates a degree of sparkle in an image in the OLED display unit 10 when the anti-glare cover 30 includes the anti-glare substrate 40 and the light-scattering layer 50. The smaller the second sparkle index value S2, the smaller the sparkle in the image, which enables the observer to easily observe the image. The method for measuring the second sparkle index value S2 is as follows. The anti-glare cover 30 formed of the anti-glare substrate 40 and the light-scattering layer 50 is installed on the image display surface 21 of the OLED display 20 with the irregular surface 41a facing up. The image display surface 21 of the OLED display 20 is imaged through the anti-glare cover 30 by a camera of a measurement device SMS-1000 manufactured by D&MS in a state in which only the green subpixels 22G among the pixels 22 emit light. After the position of the anti-glare substrate 40 is shifted by 1.0 mm, the image display surface 21 of the OLED display 20 is imaged again through the anti-glare cover 30. Then a Sparkle value, which is obtained by performing image analysis by inputting 0 to the Pixel Ratio value using a Difference Image Method (DIM) of the measurement device, is the second sparkle index value S2. S2 is expressed by %. The distance between the light shielding plate attached to the camera and the anti-glare cover 30 is set in such a way that the absolute value of the optical magnification m becomes 0.0962, and the focus of the lens is aligned with the pixels 22 of the OLED display 20. In this case, the distance between the light shielding plate attached to the camera and the anti-glare cover 30 is about 600 mm. As the lens of the camera, a 23FM50SP lens having a focal distance of 50 mm is used at an aperture of 16. Further, in order to accurately adjust the aperture to 16, the light intensity value (Intensity) and the exposure time at an aperture of 2.8, which is fully open, are recorded, the exposure time is set to 32 times of the exposure time at the aperture of 2.8 in such a way that the area of the aperture becomes 1/32 of the case where the aperture is 2.8, and the aperture of the lens is adjusted in such a way that the light intensity value becomes the same as that of the case where the aperture is 2.8.

The second white blurring index value M2 indicates a degree of white blurring in the image in the OLED display unit 10 when the anti-glare cover 30 includes the anti-glare substrate 40 and the light-scattering layer 50. The smaller the second white blurring index value M2, the less white blurring appears in the image, which enables the observer to easily observe the image. The method for measuring the second white blurring index value M2 is as follows. First, the anti-glare cover 30 formed of the anti-glare substrate 40 and the light-scattering layer 50 is installed on the image display surface 21 of the OLED display 20 with its irregular surface 41a facing up. At this time, the gap between the OLED display 20 and the anti-glare cover 30 is filled with water. When the light-scattering layer 50 also serves as a bonding layer, the OLED display 20 and the anti-glare cover 30 may be directly bonded to each other. Green light having a wavelength of 525 nm is made incident on the irregular surface 41a at an incident angle of 40° using Mini-Diff V2 manufactured by Synopsys, and a bidirectional reflectance distribution function (BRDF) is measured on the incident surface (a plane including a normal line at a point of incidence and incident light) in a direction of a reflection angle of 20°. The measurement value of BRDF is the second white blurring index value M2. In this example, measurement is performed in a reflection measurement mode. The unit of M2 is (1/sr).

The second clarity index value C2 indicates a degree of clarity of the image in the OLED display unit 10 when the anti-glare cover 30 includes the anti-glare substrate 40 and the light-scattering layer 50. The greater the second clarity index value C2, the clearer the image, which enables the observer to easily observe the image. The method for measuring the second clarity index value C2 is as follows. The anti-glare cover 30 formed of the anti-glare substrate 40 and the light-scattering layer 50 is installed on the image display surface 21 of the OLED display 20 with the irregular surface 41a of the anti-glare substrate 40 facing up. A stripe pattern with alternating white and black lines is imaged through the anti-glare substrate 40 by a camera of a measurement device SMS-1000 manufactured by D&MS in a state in which the OLED display 20 displays the stripe pattern. Each of the white lines is formed by turning on two consecutive pixels 22 in a width direction of the white line. Each of the black lines is formed by turning off two consecutive pixels 22 in a width direction of the black line. A value obtained by measuring the intensity distribution of the captured image and substituting a peak value Sp2 and a valley value Sv2 of the intensity distribution into the following Equation (5) is the second clarity index value C2. C2 is expressed by %.

$$C 2 = ( Sp 2 - Sv 2 ) / ( Sp 2 + Sv 2 ) \times 100 \qquad Equation ( 5 )$$

In this example, measurement is performed in a Distinctness of Image (DOI) measurement mode. As the lens of the camera, a 23FM50SP lens having a focal distance of 50 mm is used at an aperture of 16. The distance between the light shielding plate attached to the camera and the anti-glare cover 30 is set in such a way that the absolute value of the optical magnification m becomes 0.0962, and the the focus of the lens is aligned with the pixels 22 of the OLED display 20.

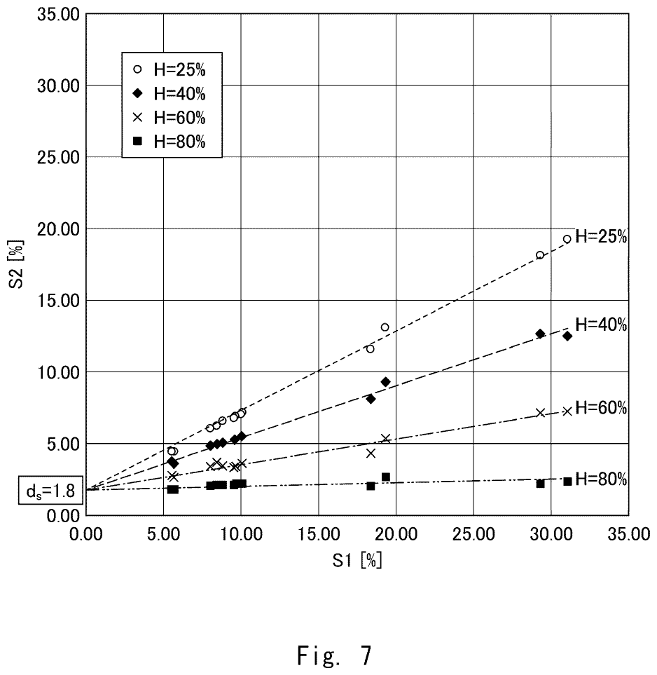

FIG. 7 shows a relation between S1 and S2 shown in FIG. 6 for each H. FIG. 7 shows that, when His constant, the relation between S1 and S2 can be approximated by a linear equation. When an intercept ds of the linear equation is 1.8, the relation between S1 and S2 can be approximated well by any H. FIG. 7 shows that the greater the H, the smaller the slope of the linear equation.

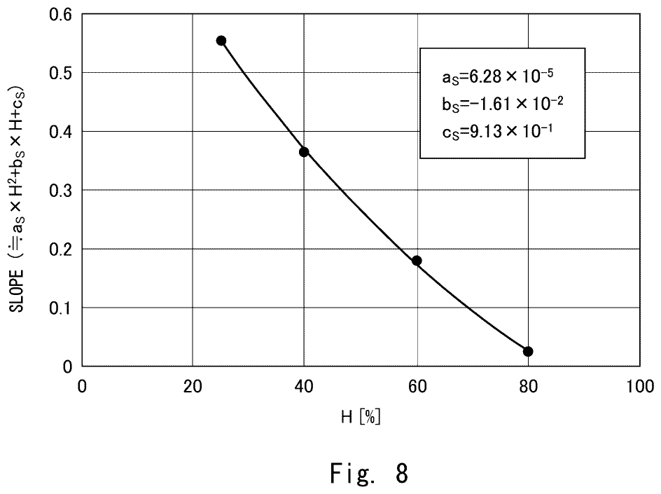

FIG. 8 shows a relation between the slope of the linear equation shown in FIGS. 7 and H. FIG. 8 shows that the slope of the linear equation shown in FIG. 7 can be approximated by a quadratic equation of H (aₛ×H²+bₛ×H+cₛ). By approximating the slope of the linear equation shown in FIG. 7 by a least-squares method, aₛ is 6.28×10⁻⁵, bₛ is −1.61×10⁻², and cₛ is 9.13 ×10⁻¹.

FIGS. 7 and 8 show that the predicted value S3 in S2 can be calculated by substituting S1 and H into the following Equation (6).

$$S 3 = S 1 \times ( {a}_{S} \times {H}^{2} + {b}_{S} \times H + {c}_{S} ) + {d}_{S} \qquad Equation ( 6 )$$

FIG. 13 shows a result of calculating S3. The comparison between FIG. 13 and FIG. 6 shows that S3, which is the predicted value, substantially coincides with S2, which is the actual measurement value.

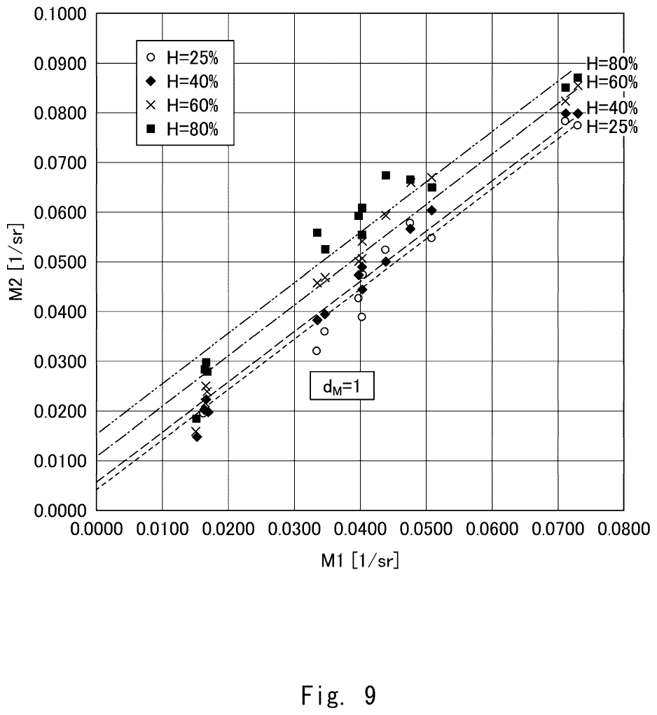

FIG. 9 shows a relation between M1 and M2 shown in FIG. 6 for each H. FIG. 9 shows that, when His constant, the relation between M1 and M2 can be approximated by a linear equation. When a slope d_{M} of the linear equation is 1, the relation between M1 and M2 can be approximated well by any H. FIG. 9 also shows that the greater the H, the greater the intercept of the linear equation.

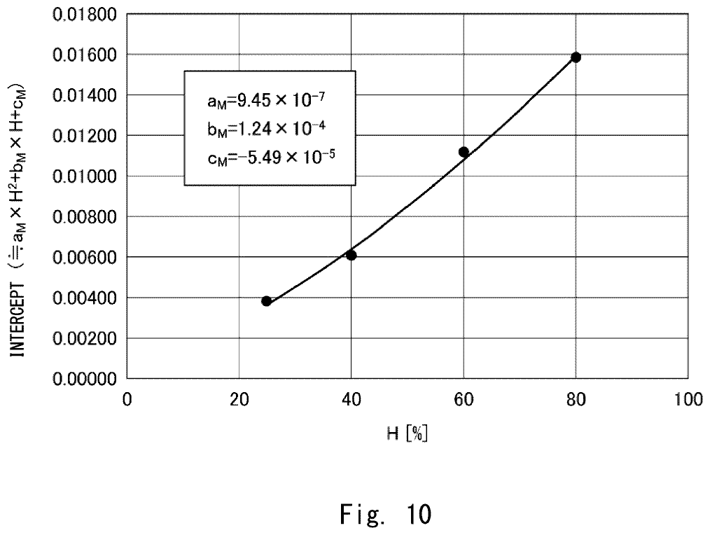

FIG. 10 shows a relation between the intercept of the linear equation shown in FIGS. 9 and H. FIG. 10 shows that the intercept of the linear equation shown in FIG. 9 can be approximated by a quadratic equation of H (a_{M}× H²+b_{M}×H+c_{M}). When the intercept of the linear equation shown in FIG. 9 is approximated by a least-squares method, am is 9.45×10⁻⁷, b_{M} is 1.24×10⁻⁴, and c_{M} is −5.49×10⁻⁵.

FIGS. 9 and 10 show that the predicted value M3 in M2 can be calculated by substituting M1 and H into the following Equation (7).

$$M 3 = M 1 \times {d}_{M} + ( {a}_{M} \times {H}^{2} + {b}_{M} \times H + {c}_{M} ) \qquad Equation ( 7 )$$

FIG. 13 shows a result of calculating M3. The comparison between FIG. 13 and FIG. 6 shows that M3, which is the predicted value, substantially coincides with M2, which is the actual measurement value.

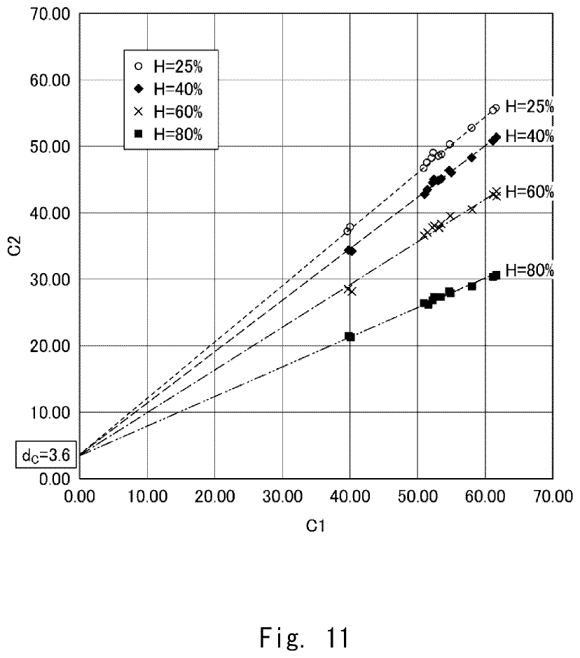

FIG. 11 shows a relation between C1 and C2 shown in FIG. 6 for each H. FIG. 11 shows that when His constant, the relation between C1 and C2 can be approximated by a linear equation. When an intercept dc of the linear equation is 3.6, the relation between C1 and C2 can be approximated well by any H. FIG. 11 also shows that the greater the H, the smaller the slope of the linear equation.

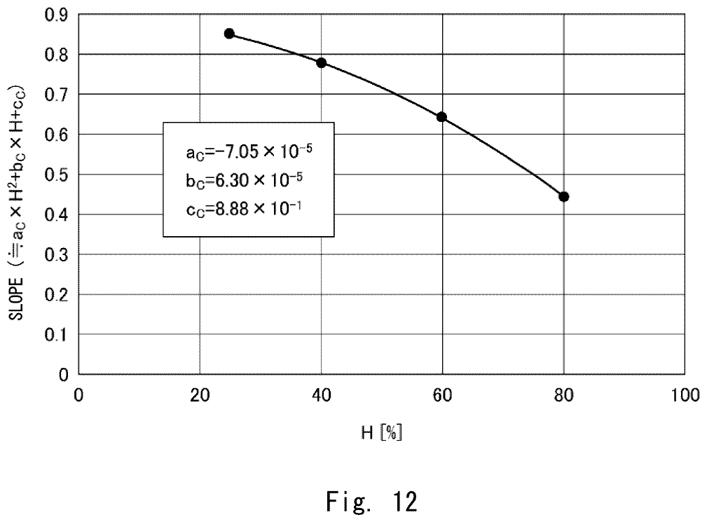

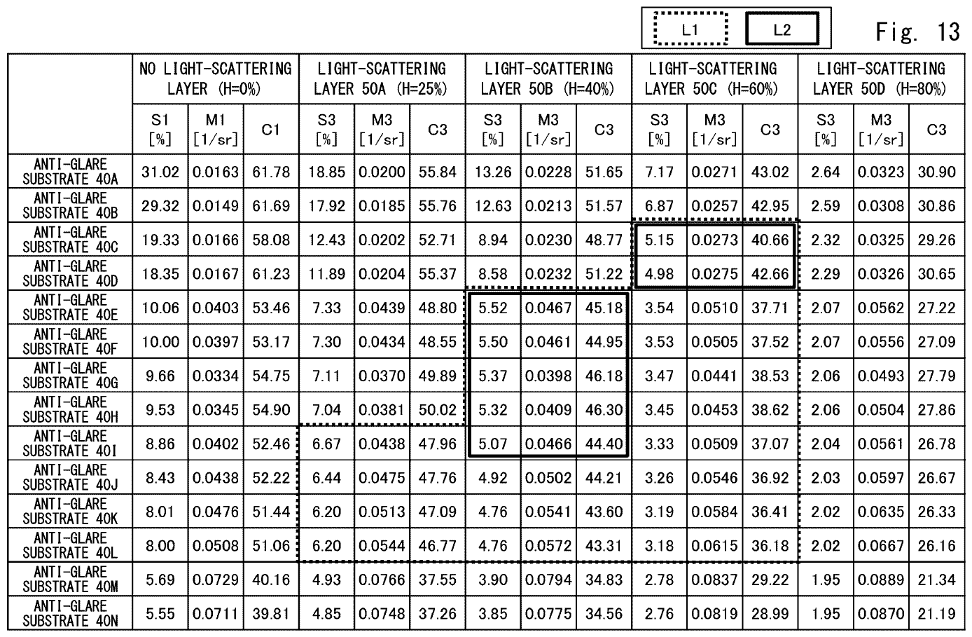

FIG. 12 shows a relation between the slope of the linear equation shown in FIGS. 11 and H. FIG. 12 shows that the slope of the linear equation shown in FIG. 11 can be approximated by a quadratic equation of H (a_{c}× H²+b_{c}×H+c_{c}). When the slope of the linear equation shown in FIG. 11 is approximated by a least-squares method, a_{c} is −7.05×10⁻⁵, b_{c} is 6.30×10⁻⁵, and c_{c} is 8.88×10⁻¹.

FIGS. 11 and 12 show that the predicted value C3 in C2 can be calculated by substituting C1 and H into the following Equation (8).

$$C 3 = C 1 \times ( {a}_{C} \times {H}^{2} + {b}_{C} \times H + {c}_{C} ) + {d}_{C} \qquad Equation ( 8 )$$

FIG. 13 shows a result of calculating C3. The comparison between FIG. 13 and FIG. 6 shows that C3, which is the predicted value, substantially coincides with C2, which is the actual measurement value.

The present inventors have found an appropriate combination of the anti-glare substrate 40 with the light-scattering layer 50 by using the first sparkle index value S1(%), the first white blurring index value M1 (/sr), and the first clarity index value C1(%) as characteristic values of the anti-glare substrate 40 and using the Haze value H (%) as the characteristic value of the light-scattering layer 50.

The anti-glare substrate 40 and the light-scattering layer 50 preferably select a combination that satisfies the following Equations (1) to (3).

$$S 1 \times ( {a}_{S} \times {H}^{2} + {b}_{S} \times H + {c}_{S} ) + {d}_{S} = S 3 < 6.79 \qquad Equation ( 1 )$$

$$M 1 \times {d}_{M} + ( {a}_{M} \times {H}^{2} + {b}_{M} \times H + {c}_{M} ) = M 3 \leq 0.067 \qquad Equation ( 2 )$$

$$C 1 \times ( {a}_{C} \times {H}^{2} + {b}_{C} \times H + {c}_{C} ) + {d}_{C} = C 3 \geq 35. \qquad Equation ( 3 )$$

In FIG. 13, the range surrounded by a thick line L1 is a combination that satisfies the Equations (1) to (3).

By selecting the combination that satisfies the Equations (1) to (3), as will be clear from FIG. 6, the second sparkle index value S2(%) can be set below 6.79, the second white blurring index value M2 (/sr) can be set to 0.0670 or less, and the second clarity index value C2 can be set to 35.00 or more. It is therefore possible to suppress sparkle in an image, white blurring in the image, and a decrease in the clarity of the image in the anti-glare cover 30 for the OLED display 20.

The anti-glare substrate 40 and the light-scattering layer 50 preferably select a combination that satisfies the following Equations (1A) to (3A).

$$S 1 \times ( {a}_{S} \times {H}^{2} + {b}_{S} \times H + {c}_{S} ) + {d}_{S} = S 3 < 6. \qquad Equation ( 1 A )$$

$$M 1 \times {d}_{M} + ( {a}_{M} \times {H}^{2} + {b}_{M} \times H + {c}_{M} ) = M 3 \leq 0.05 \qquad Equation ( 2 A )$$

$$C 1 \times ( {a}_{C} \times {H}^{2} + {b}_{C} \times H + {c}_{C} ) + {d}_{C} = C 3 \geq 40. \qquad Equation ( 3 A )$$

In FIG. 13, a range surrounded by a thick line L2 is a combination that satisfies the Equations (1A) to (3A).

By selecting a combination that satisfies Equations (1A) to (3A), as will be clear from FIG. 6, the second sparkle index value S2(%) can be made smaller than 6.00, the second white blurring index value M2 (/sr) can be made smaller than 0.0500, and the second clarity index value C2 can be made 40.00 or more. It is therefore possible to further suppress sparkle in an image, white blurring in the image, and a decrease in the clarity of the image in the anti-glare cover 30 for the OLED display 20.

With regard to the above-described embodiment, the following Supplementary Notes are disclosed.

### [Supplementary Note 1]

A method for manufacturing an anti-glare cover provided on an image display surface of an Organic Light Emitting Diode (OLED) display, wherein
the anti-glare cover includes an anti-glare substrate having an irregular surface on a surface on a side opposite to the image display surface of the OLED display and a light-scattering layer disposed between the anti-glare substrate and the OLED display,
the OLED display has a plurality of pixels, and each of the pixels includes red subpixels that emit red light, green subpixels that emit green light, and blue subpixels that emit blue light,
a ratio (ΔA_{G}/A0) of a difference ΔA_{G} (ΔA_{G}=A0-A1_{G}) between an average value A0 of a total area of each of the pixels and an average value A1G of a total light-emitting area of all the green subpixels included in each of the pixels to the average value A0 is 85% to 95%,
a pixel density is 170 ppi to 650 ppi, and
the manufacturing method comprises:
selecting a combination of the anti-glare substrate with the light-scattering layer that satisfies the following Equations (1), (2), and (3):

$$S 1 \times ( {a}_{S} \times {H}^{2} + {b}_{S} \times H + {c}_{S} ) + {d}_{S} = S 3 < 6.79 \qquad Equation ( 1 )$$

(in Equation (1), aₛ is 6.28×10⁻⁵, bₛ is −1.61×10⁻², cₛ is 9.13×10⁻¹, and dₛ is 1.8);

$$M 1 \times {d}_{M} + ( {a}_{M} \times {H}^{2} + {b}_{M} \times H + {c}_{M} ) = M 3 \leq 0.067 \qquad Equation ( 2 )$$

(in Equation (2), a_{M} is 9.45 ×10⁻⁷, b_{M} is 1.24×10⁻⁴, c_{M} is −5.49 ×10⁻⁵, and d_{M} is 1); and

$$C 1 \times ( {a}_{C} \times {H}^{2} + {b}_{C} \times H + {c}_{C} ) + {d}_{C} = C 3 \geq 35. \qquad Equation ( 3 )$$

(in Equation (3), a_{c} is −7.05×10⁻⁵, b_{c} is 6.30×10⁻⁵, c_{c} is 8.88×10⁻¹, and d_{c} is 3.6); and
forming the anti-glare substrate and the light-scattering layer in the selected combination.

First sparkle index value S1: the anti-glare substrate is installed on the image display surface of the OLED display with its irregular surface facing up without the light-scattering layer interposed therebetween. The image display surface of the OLED display is imaged through the anti-glare substrate by a camera of a measurement device SMS-1000 manufactured by D&MS in a state in which only the green subpixels, of the pixels, emit light. A Sparkle value obtained by performing image analysis by the measurement device is the first sparkle index value S1. S1 is expressed by %. A distance between the light shielding plate attached to the camera and the anti-glare substrate is about 600 mm. As the lens of the camera, a 23FM50SP lens having a focal distance of 50 mm is used at an aperture of 16.

First white blurring index value M1: the anti-glare substrate is installed horizontally on the image display surface of the OLED display with its irregular surface facing up without the light-scattering layer interposed therebetween. Green light having a wavelength of 525 nm is made incident on the irregular surface at an incident angle of 40° by using Mini-Diff V2 manufactured by Synopsys, and a bidirectional reflectance distribution function (BRDF) is measured on the incident surface (a plane including a normal line at a point of incidence and incident light) in a direction of a reflection angle of 20°. A measurement value of BRDF is the first white blurring index value M1. The unit of M1 is (1/sr).

First clarity index value C1: the anti-glare substrate is installed on the image display surface of the OLED display with its irregular surface facing up without the light-scattering layer interposed therebetween. A stripe pattern with alternating white and black lines is imaged through the anti-glare substrate by a camera of a measurement device SMS-1000 manufactured by D&MS in a state in which the OLED display displays the stripe pattern. Each of the white lines is formed by turning on two consecutive pixels in a width direction of the white line. Each of the black lines is formed by turning off two consecutive pixels in a width direction of the black line. A value obtained by measuring an intensity distribution of the captured image and substituting a peak value Sp1 and a valley value Sv1 of the intensity distribution into the following Equation (4) is the first clarity index value C1. C1 is expressed by %.

$$C 1 = ( Sp 1 - Sv 1 ) / ( Sp 1 + Sv 1 ) \times 100 \qquad Equation ( 4 )$$

As the lens of the camera, a 23FM50SP lens having a focal distance of 50 mm is used at an aperture of 16. A distance between the light shielding plate attached to the camera and the anti-glare substrate is set in such a way that an absolute value of an optical magnification m becomes 0.0962. A focus of the lens is aligned with pixels of the OLED display.

Haze value H: a percentage of transmitted light that is deviated from the incident light by 2.5° or more by forward scattering, of transmitted light that transmits through the light-scattering layer in a thickness direction, is the Haze value H.

### [Supplementary Note 2]

The method for manufacturing the anti-glare cover according to Supplementary Note 1, comprising:
selecting a combination of the anti-glare substrate with the light-scattering layer that satisfies the following Equations (1A), (2A) and (3A):

$$S 3 < 6. ; \qquad Equation ( 1 A )$$

$$M 3 < 0.05 ; \qquad Equation ( 2 A )$$

$$C 3 \geq 40. ; \qquad Equation ( 3 A )$$

and forming the anti-glare substrate and the light-scattering layer in the selected combination.

### [Supplementary Note 3]

The method for manufacturing the anti-glare cover according to Supplementary Note 1 or 2, wherein the anti-glare substrate is a glass substrate and the irregular surface is formed of glass.

### [Supplementary Note 4]

The method for manufacturing the anti-glare cover according to any one of Supplementary Notes 1 to 3, wherein the light-scattering layer includes a resin layer and a plurality of particles dispersed inside the resin layer.

### [Supplementary Note 5]

A method for manufacturing an Organic Light Emitting Diode (OLED) display unit including the OLED display and an anti-glare cover provided on an image display surface of the OLED display, wherein
the anti-glare cover includes an anti-glare substrate having an irregular surface on a surface on a side opposite to the image display surface of the OLED display and a light-scattering layer disposed between the anti-glare substrate and the OLED display,
the OLED display has a plurality of pixels, and each of the pixels includes red subpixels that emit red light, green subpixels that emit green light, and blue subpixels that emit blue light,
a ratio (ΔA_{G}/A0) of a difference ΔA_{G} (ΔA_{G}=A0-A1_{G}) between an average value A0 of a total area of each of the pixels and an average value A1G of a total light-emitting area of all the green subpixels included in each of the pixels to the average value A0 is 85% to 95%,
a pixel density is 170 ppi to 650 ppi, and
the manufacturing method includes:
selecting a combination of the anti-glare substrate with the light-scattering layer that satisfies the following Equations (1), (2), and (3):

$$S 1 \times ( {a}_{S} \times {H}^{2} + {b}_{S} \times H + {c}_{S} ) + {d}_{S} = S 3 < 6.79 \qquad Equation ( 1 )$$

(in Equation (1), aₛ is 6.28 ×10⁻⁵, bₛ is −1.61×10⁻², cₛ is 9.13 ×10⁻¹, and dₛ is 1.8);

$$M 1 \times {d}_{M} + ( {a}_{M} \times {H}^{2} + {b}_{M} \times H + {c}_{M} ) = M 3 \leq 0.067 \qquad Equation ( 2 )$$

(in Equation (2), a_{M} is 9.45 ×10⁻⁷, b_{M} is 1.24×10⁻⁴, c_{M} is −5.49 ×10⁻⁵, and d_{M} is 1); and

$$C 1 \times ( {a}_{C} \times {H}^{2} + {b}_{C} \times H + {c}_{C} ) + {d}_{C} = C 3 \geq 35. \qquad Equation ( 3 )$$

(in Equation (3), a_{c} is −7.05×10⁻⁵, b_{c} is 6.30×10⁻⁵, c_{c} is 8.88×10⁻¹, and d_{c} is 3.6); and
forming the anti-glare substrate and the light-scattering layer in the selected combination.

First sparkle index value S1: the anti-glare substrate is installed on the image display surface of the OLED display with its irregular surface facing up without the light-scattering layer interposed therebetween. The image display surface of the OLED display is imaged through the anti-glare substrate by a camera of a measurement device SMS-1000 manufactured by D&MS in a state in which only the green subpixels, of the pixels, emit light. A Sparkle value obtained by performing image analysis by the measurement device is the first sparkle index value S1. S1 is expressed by %. A distance between the light shielding plate attached to the camera and the anti-glare substrate is about 600 mm. As the lens of the camera, a 23FM50SP lens having a focal distance of 50 mm is used at an aperture of 16.

First white blurring index value M1: the anti-glare substrate is installed horizontally on the image display surface of the OLED display with its irregular surface facing up without the light-scattering layer interposed therebetween. Green light having a wavelength of 525 nm is made incident on the irregular surface at an incident angle of 40° by using Mini-Diff V2 manufactured by Synopsys, and a bidirectional reflectance distribution function (BRDF) is measured on the incident surface (a plane including a normal line at a point of incidence and incident light) in a direction of a reflection angle of 20°. A measurement value of BRDF is the first white blurring index value M1. The unit of M1 is (1/sr).

First clarity index value C1: the anti-glare substrate is installed on the image display surface of the OLED display with its irregular surface facing up without the light-scattering layer interposed therebetween. A stripe pattern with alternating white and black lines is imaged through the anti-glare substrate by a camera of a measurement device SMS-1000 manufactured by D&MS in a state in which the OLED display displays the stripe pattern. Each of the white lines is formed by turning on two consecutive pixels in a width direction of the white line. Each of the black lines is formed by turning off two consecutive pixels in a width direction of the black line. A value obtained by measuring an intensity distribution of the captured image and substituting a peak value Sp1 and a valley value Sv1 of the intensity distribution into the following Equation (4) is the first clarity index value C1. C1 is expressed by %.

$$C 1 = ( Sp 1 - Sv 1 ) / ( Sp 1 + Sv 1 ) \times 100 \qquad Equation ( 4 )$$

As the lens of the camera, a 23FM50SP lens having a focal distance of 50 mm is used at an aperture of 16. A distance between the light shielding plate attached to the camera and the anti-glare substrate is set in such a way that an absolute value of an optical magnification m becomes 0.0962. A focus of the lens is aligned with pixels of the OLED display.

Haze value H: a percentage of transmitted light that is deviated from the incident light by 2.5° or more by forward scattering, of transmitted light that transmits through the light-scattering layer in a thickness direction, is the Haze value H.

### [Supplementary Note 6]

An anti-glare cover provided on an image display surface of an Organic Light Emitting Diode (OLED) display, wherein
the anti-glare cover includes an anti-glare substrate having an irregular surface on a surface on a side opposite to the image display surface of the OLED display and a light-scattering layer disposed between the anti-glare substrate and the OLED display,
the OLED display has a plurality of pixels, and each of the pixels includes red subpixels that emit red light, green subpixels that emit green light, and blue subpixels that emit blue light,
a ratio (ΔA_{G}/A0) of a difference ΔA_{G} (ΔA_{G}=A0-A1_{G}) between an average value A0 of a total area of each of the pixels and an average value A1G of a total light-emitting area of all the green subpixels included in each of the pixels to the average value A0 is 85% to 95%,
a pixel density is 170 ppi to 650 ppi, and
the anti-glare substrate and the light-scattering layer satisfy the following equations (1), (2), and (3):

$$S 1 \times ( {a}_{S} \times {H}^{2} + {b}_{S} \times H + {c}_{S} ) + {d}_{S} = S 3 < 6.79 \qquad Equation ( 1 )$$

(in Equation (1), aₛ is 6.28×10⁻⁵, bₛ is −1.61×10⁻², cₛ is 9.13 ×10⁻¹, and dₛ is 1.8);

$$M 1 \times {d}_{M} + ( {a}_{M} \times {H}^{2} + {b}_{M} \times H + {c}_{M} ) = M 3 \leq 0.067 \qquad Equation ( 2 )$$

(in Equation (2), a_{M} is 9.45×10⁻⁷, b_{M} is 1.24×10⁻⁴, c_{M} is −5.49×10⁻⁵, and d_{M} is 1); and

$$C 1 \times ( {a}_{c} \times {H}^{2} + {b}_{c} \times H + {c}_{c} ) + {d}_{c} = C 3 \geq 35. \qquad Equation ( 3 )$$

(in Equation (3), a_{c} is −7.05×10⁻⁵, b_{c} is 6.30×10⁻⁵, c_{c} is 8.88 ×10⁻¹, and d_{c} is 3.6).

First sparkle index value S1: the anti-glare substrate is installed on the image display surface of the OLED display with its irregular surface facing up without the light-scattering layer interposed therebetween. The image display surface of the OLED display is imaged through the anti-glare substrate by a camera of a measurement device SMS-1000 manufactured by D&MS in a state in which only the green subpixels, of the pixels, emit light. A Sparkle value obtained by performing image analysis by the measurement device is the first sparkle index value S1. S1 is expressed by %. A distance between the light shielding plate attached to the camera and the anti-glare substrate is about 600 mm. As the lens of the camera, a 23FM50SP lens having a focal distance of 50 mm is used at an aperture of 16.

First white blurring index value M1: the anti-glare substrate is installed horizontally on the image display surface of the OLED display with its irregular surface facing up without the light-scattering layer interposed therebetween. Green light having a wavelength of 525 nm is made incident on the irregular surface at an incident angle of 40° by using Mini-Diff V2 manufactured by Synopsys, and a bidirectional reflectance distribution function (BRDF) is measured on the incident surface (a plane including a normal line at a point of incidence and incident light) in a direction of a reflection angle of 20°. A measurement value of BRDF is the first white blurring index value M1. The unit of M1 is (1/sr).

First clarity index value C1: the anti-glare substrate is installed on the image display surface of the OLED display with its irregular surface facing up without the light-scattering layer interposed therebetween. A stripe pattern with alternating white and black lines is imaged through the anti-glare substrate by a camera of a measurement device SMS-1000 manufactured by D&MS in a state in which the OLED display displays the stripe pattern. Each of the white lines is formed by turning on two consecutive pixels in a width direction of the white line. Each of the black lines is formed by turning off two consecutive pixels in a width direction of the black line. A value obtained by measuring an intensity distribution of the captured image and substituting a peak value Sp1 and a valley value Sv1 of the intensity distribution into the following Equation (4) is the first clarity index value C1. C1 is expressed by %.

$$C 1 = ( Sp 1 - Sv 1 ) / ( Sp 1 + Sv 1 ) \times 100 \qquad Equation ( 4 )$$

As the lens of the camera, a 23FM50SP lens having a focal distance of 50 mm is used at an aperture of 16. A distance between the light shielding plate attached to the camera and the anti-glare substrate is set in such a way that an absolute value of an optical magnification m becomes 0.0962. A focus of the lens is aligned with pixels of the OLED display.

Haze value H: a percentage of transmitted light that is deviated from the incident light by 2.5° or more by forward scattering, of transmitted light that transmits through the light-scattering layer in a thickness direction, is the Haze value H.

### [Supplementary Note 7]

An OLED display unit comprising the anti-glare cover according to Supplementary Note 6 and the OLED display.

While the method for manufacturing the anti-glare cover, the method for manufacturing the OLED display unit, the anti-glare cover, and the OLED display unit according to the present disclosure have been described above, the present disclosure is not limited to the above embodiment. Various changes, modifications, substitutions, additions, deletions, and combinations thereof are possible within the scope of the claims. They also naturally fall within the technical scope of the present disclosure.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. A method for manufacturing an anti-glare cover provided on an image display surface of an Organic Light Emitting Diode (OLED) display, wherein
the anti-glare cover includes an anti-glare substrate having an irregular surface on a surface on a side opposite to the image display surface of the OLED display and a light-scattering layer disposed between the anti-glare substrate and the OLED display,
the OLED display has a plurality of pixels, and each of the pixels includes red subpixels that emit red light, green subpixels that emit green light, and blue subpixels that emit blue light,
a ratio (ΔA_{G}/A0) of a difference ΔA_{G} (ΔA_{G}=A0-A1_{G}) between an average value A0 of a total area of each of the pixels and an average value A1G of a total light-emitting area of all the green subpixels included in each of the pixels to the average value A0 is 85% to 95%,
a pixel density is 170 ppi to 650 ppi, and
the manufacturing method comprises:
selecting a combination of the anti-glare substrate with the light-scattering layer that satisfies the following Equations (1), (2), and (3):
$$S 1 \times ( {a}_{s} \times {H}^{2} + {b}_{s} \times H + {c}_{s} ) + {d}_{S} = S 3 < 6.79 \qquad Equation ( 1 )$$
(in Equation (1), aₛ is 6.28×10⁻⁵, bₛ is −1.61×10⁻², cₛ is 9.13×10⁻¹, and dₛ is 1.8)
$$M 1 \times {d}_{M} + ( {a}_{M} \times {H}^{2} + {b}_{M} \times H + {c}_{M} ) = M 3 \leq 0.067 \qquad Equation ( 2 )$$
(in Equation (2), a_{M} is 9.45×10⁻⁷, b_{M} is 1.24×10⁻⁴, c_{M} is −5.49×10⁻⁵, and d_{M} is 1); and
$$C 1 \times ( {a}_{c} \times {H}^{2} + {b}_{c} \times H + {c}_{c} ) + {d}_{c} = C 3 \geq 35. \qquad Equation ( 3 )$$
(in Equation (3), a_{c} is −7.05×10⁻⁵, b_{c} is 6.30×10⁻⁵, c_{c} is 8.88 ×10⁻¹, and d_{c} is 3.6); and
forming the anti-glare substrate and the light-scattering layer in the selected combination.
First sparkle index value S1: the anti-glare substrate is installed on the image display surface of the OLED display with its irregular surface facing up without the light-scattering layer interposed therebetween. The image display surface of the OLED display is imaged through the anti-glare substrate by a camera of a measurement device SMS-1000 manufactured by D&MS in a state in which only the green subpixels, of the pixels, emit light. A Sparkle value obtained by performing image analysis by the measurement device is the first sparkle index value S1. S1 is expressed by %. A distance between the light shielding plate attached to the camera and the anti-glare substrate is about 600 mm. As the lens of the camera, a 23FM50SP lens having a focal distance of 50 mm is used at an aperture of 16.
First white blurring index value M1: the anti-glare substrate is installed horizontally on the image display surface of the OLED display with its irregular surface facing up without the light-scattering layer interposed therebetween. Green light having a wavelength of 525 nm is made incident on the irregular surface at an incident angle of 40° by using Mini-Diff V2 manufactured by Synopsys, and a bidirectional reflectance distribution function (BRDF) is measured on the incident surface (a plane including a normal line at a point of incidence and incident light) in a direction of a reflection angle of 20°. A measurement value of BRDF is the first white blurring index value M1. The unit of M1 is (1/sr).
First clarity index value C1: the anti-glare substrate is installed on the image display surface of the OLED display with its irregular surface facing up without the light-scattering layer interposed therebetween. A stripe pattern with alternating white and black lines is imaged through the anti-glare substrate by a camera of a measurement device SMS-1000 manufactured by D&MS in a state in which the OLED display displays the stripe pattern. Each of the white lines is formed by turning on two consecutive pixels in a width direction of the white line. Each of the black lines is formed by turning off two consecutive pixels in a width direction of the black line. A value obtained by measuring an intensity distribution of the captured image and substituting a peak value Sp1 and a valley value Sv1 of the intensity distribution into the following Equation (4) is the first clarity index value C1. C1 is expressed by %.
$$C 1 = ( Sp 1 - Sv 1 ) / ( Sp 1 + Sv 1 ) \times 100 \qquad Equation ( 4 )$$
As the lens of the camera, a 23FM50SP lens having a focal distance of 50 mm is used at an aperture of 16. A distance between the light shielding plate attached to the camera and the anti-glare substrate is set in such a way that an absolute value of an optical magnification m becomes 0.0962. A focus of the lens is aligned with pixels of the OLED display.
Haze value H: a percentage of transmitted light that is deviated from the incident light by 2.5° or more by forward scattering, of transmitted light that transmits through the light-scattering layer in a thickness direction, is the Haze value H.

2. The method for manufacturing the anti-glare cover according to claim 1, comprising:
selecting a combination of the anti-glare substrate with the light-scattering layer that satisfies the following Equations (1A), (2A) and (3A):
$$S 3 < 6. ; \qquad Equation ( 1 A )$$
$$M 3 < 0.05 ; \qquad Equation ( 2 A )$$
$$C 3 \geq 40. ; \qquad Equation ( 3 A )$$
and
forming the anti-glare substrate and the light-scattering layer in the selected combination.

3. The method for manufacturing the anti-glare cover according to claim 1, wherein the anti-glare substrate is a glass substrate and the irregular surface is formed of glass.

4. The method for manufacturing the anti-glare cover according to claim 1, wherein the light-scattering layer includes a resin layer and a plurality of particles dispersed inside the resin layer.

5. A method for manufacturing an Organic Light Emitting Diode (OLED) display unit including the OLED display and an anti-glare cover provided on an image display surface of the OLED display, wherein
the anti-glare cover includes an anti-glare substrate having an irregular surface on a surface on a side opposite to the image display surface of the OLED display and a light-scattering layer disposed between the anti-glare substrate and the OLED display,
the OLED display has a plurality of pixels, and each of the pixels includes red subpixels that emit red light, green subpixels that emit green light, and blue subpixels that emit blue light,
a ratio (ΔA_{G}/A0) of a difference ΔA_{G} (ΔA_{G}=A0-A1_{G}) between an average value A0 of a total area of each of the pixels and an average value A1G of a total light-emitting area of all the green subpixels included in each of the pixels to the average value A0 is 85% to 95%,
a pixel density is 170 ppi to 650 ppi, and
the manufacturing method includes:
selecting a combination of the anti-glare substrate with the light-scattering layer that satisfies the following Equations (1), (2), and (3):
$$S 1 \times ( {a}_{s} \times {H}^{2} + {b}_{s} \times H + {c}_{s} ) + {d}_{S} = S 3 < 6.79 \qquad Equation ( 1 )$$
(in Equation (1), aₛ is 6.28×10⁻⁵, bₛ is −1.61×10⁻², cₛ is 9.13 ×10⁻¹, and dₛ is 1.8);
$$M 1 \times {d}_{M} + ( {a}_{M} \times {H}^{2} + {b}_{M} \times H + {c}_{M} ) = M 3 \leq 0.067 \qquad Equation ( 2 )$$
(in Equation (2), a_{M} is 9.45×10⁻⁷, b_{M} is 1.24×10⁻⁴, c_{M} is −5.49×10⁻⁵, and d_{M} is 1); and
$$C 1 \times ( {a}_{c} \times {H}^{2} + {b}_{c} \times H + {c}_{c} ) + {d}_{c} = C 3 \geq 35. \qquad Equation ( 3 )$$
(in Equation (3), a_{c} is −7.05×10⁻⁵, b_{c} is 6.30×10⁻⁵, c_{c} is 8.88×10⁻¹, and d_{c} is 3.6); and
forming the anti-glare substrate and the light-scattering layer in the selected combination.
First sparkle index value S1: the anti-glare substrate is installed on the image display surface of the OLED display with its irregular surface facing up without the light-scattering layer interposed therebetween. The image display surface of the OLED display is imaged through the anti-glare substrate by a camera of a measurement device SMS-1000 manufactured by D&MS in a state in which only the green subpixels, of the pixels, emit light. A Sparkle value obtained by performing image analysis by the measurement device is the first sparkle index value S1. S1 is expressed by %. A distance between the light shielding plate attached to the camera and the anti-glare substrate is about 600 mm. As the lens of the camera, a 23FM50SP lens having a focal distance of 50 mm is used at an aperture of 16.
First white blurring index value M1: the anti-glare substrate is installed horizontally on the image display surface of the OLED display with its irregular surface facing up without the light-scattering layer interposed therebetween. Green light having a wavelength of 525 nm is made incident on the irregular surface at an incident angle of 40° by using Mini-Diff V2 manufactured by Synopsys, and a bidirectional reflectance distribution function (BRDF) is measured on the incident surface (a plane including a normal line at a point of incidence and incident light) in a direction of a reflection angle of 20°. A measurement value of BRDF is the first white blurring index value M1. The unit of M1 is (1/sr).
First clarity index value C1: the anti-glare substrate is installed on the image display surface of the OLED display with its irregular surface facing up without the light-scattering layer interposed therebetween. A stripe pattern with alternating white and black lines is imaged through the anti-glare substrate by a camera of a measurement device SMS-1000 manufactured by D&MS in a state in which the OLED display displays the stripe pattern. Each of the white lines is formed by turning on two consecutive pixels in a width direction of the white line. Each of the black lines is formed by turning off two consecutive pixels in a width direction of the black line. A value obtained by measuring an intensity distribution of the captured image and substituting a peak value Sp1 and a valley value Sv1 of the intensity distribution into the following Equation (4) is the first clarity index value C1. C1 is expressed by %.
$$C 1 = ( Sp 1 - Sv 1 ) / ( Sp 1 + Sv 1 ) \times 100 \qquad Equation ( 4 )$$
As the lens of the camera, a 23FM50SP lens having a focal distance of 50 mm is used at an aperture of 16. A distance between the light shielding plate attached to the camera and the anti-glare substrate is set in such a way that an absolute value of an optical magnification m becomes 0.0962. A focus of the lens is aligned with pixels of the OLED display.
Haze value H: a percentage of transmitted light that is deviated from the incident light by 2.5° or more by forward scattering, of transmitted light that transmits through the light-scattering layer in a thickness direction, is the Haze value H.

6. An anti-glare cover provided on an image display surface of an Organic Light Emitting Diode (OLED) display, wherein
the anti-glare cover includes an anti-glare substrate having an irregular surface on a surface on a side opposite to the image display surface of the OLED display and a light-scattering layer disposed between the anti-glare substrate and the OLED display,
the OLED display has a plurality of pixels, and each of the pixels includes red subpixels that emit red light, green subpixels that emit green light, and blue subpixels that emit blue light,
a ratio (ΔA_{G}/A0) of a difference ΔA_{G} (ΔA_{G}=A0-A1_{G}) between an average value A0 of a total area of each of the pixels and an average value A1G of a total light-emitting area of all the green subpixels included in each of the pixels to the average value A0 is 85% to 95%,
a pixel density is 170 ppi to 650 ppi, and
the anti-glare substrate and the light-scattering layer satisfy the following equations (1), (2), and (3):
$$S 1 \times ( {a}_{s} \times {H}^{2} + {b}_{s} \times H + {c}_{s} ) + {d}_{S} = S 3 < 6.79 \qquad Equation ( 1 )$$
(in Equation (1), aₛ is 6.28×10⁻⁵, bₛ is −1.61×10⁻², cₛ is 9.13 ×10⁻¹, and dₛ is 1.8);
$$M 1 \times {d}_{M} + ( {a}_{M} \times {H}^{2} + {b}_{M} \times H + {c}_{M} ) = M 3 \leq 0.067 \qquad Equation ( 2 )$$
(in Equation (2), a_{M} is 9.45 ×10⁻⁷, b_{M} is 1.24×10⁻⁴, c_{M} is −5.49 ×10⁻⁵, and d_{M} is 1); and
$$C 1 \times ( {a}_{c} \times {H}^{2} + {b}_{c} \times H + {c}_{c} ) + {d}_{c} = C 3 \geq 35. \qquad Equation ( 3 )$$
(in Equation (3), a_{c} is −7.05×10⁻⁵, b_{c} is 6.30×10⁻⁵, c_{c} is 8.88 ×10⁻¹, and d_{c} is 3.6).
First sparkle index value S1: the anti-glare substrate is installed on the image display surface of the OLED display with its irregular surface facing up without the light-scattering layer interposed therebetween. The image display surface of the OLED display is imaged through the anti-glare substrate by a camera of a measurement device SMS-1000 manufactured by D&MS in a state in which only the green subpixels, of the pixels, emit light. A Sparkle value obtained by performing image analysis by the measurement device is the first sparkle index value S1. S1 is expressed by %. A distance between the light shielding plate attached to the camera and the anti-glare substrate is about 600 mm. As the lens of the camera, a 23FM50SP lens having a focal distance of 50 mm is used at an aperture of 16.
First white blurring index value M1: the anti-glare substrate is installed horizontally on the image display surface of the OLED display with its irregular surface facing up without the light-scattering layer interposed therebetween. Green light having a wavelength of 525 nm is made incident on the irregular surface at an incident angle of 40° by using Mini-Diff V2 manufactured by Synopsys, and a bidirectional reflectance distribution function (BRDF) is measured on the incident surface (a plane including a normal line at a point of incidence and incident light) in a direction of a reflection angle of 20°. A measurement value of BRDF is the first white blurring index value M1. The unit of M1 is (1/sr).
First clarity index value C1: the anti-glare substrate is installed on the image display surface of the OLED display with its irregular surface facing up without the light-scattering layer interposed therebetween. A stripe pattern with alternating white and black lines is imaged through the anti-glare substrate by a camera of a measurement device SMS-1000 manufactured by D&MS in a state in which the OLED display displays the stripe pattern. Each of the white lines is formed by turning on two consecutive pixels in a width direction of the white line. Each of the black lines is formed by turning off two consecutive pixels in a width direction of the black line. A value obtained by measuring an intensity distribution of the captured image and substituting a peak value Sp1 and a valley value Sv1 of the intensity distribution into the following Equation (4) is the first clarity index value C1. C1 is expressed by %.
$$C 1 = ( Sp 1 - Sv 1 ) / ( Sp 1 + Sv 1 ) \times 100 \qquad Equation ( 4 )$$
As the lens of the camera, a 23FM50SP lens having a focal distance of 50 mm is used at an aperture of 16. A distance between the light shielding plate attached to the camera and the anti-glare substrate is set in such a way that an absolute value of an optical magnification m becomes 0.0962. A focus of the lens is aligned with pixels of the OLED display.
Haze value H: a percentage of transmitted light that is deviated from the incident light by 2.5° or more by forward scattering, of transmitted light that transmits through the light-scattering layer in a thickness direction, is the Haze value H.

7. An OLED display unit comprising the anti-glare cover according to claim 6 and the OLED display.
